(19) United States
(12) Patent Application Publication
(10) Pub. No.: US 2009/0101945 A1
(43) Pub. Date: Apr. 23, 2009

(54) SEMICONDUCTOR DEVICE

(75) Inventors: Rie YAMAGUCHI, Kanagawa-ken (JP); Osamu Fujii, Kanagawa-ken (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 12/252,134

(22) Filed: Oct. 15, 2008

(30) Foreign Application Priority Data
Oct. 16, 2007 (JP) 2007-269035

(51) Int. Cl. H01L 23/00

(52) U.S. Cl. 257/288; 257/E29.255

(57) ABSTRACT

A semiconductor device includes: a semiconductor substrate; an N-type MOSFET formed in a surface of the semiconductor substrate; a tensile stress film provided on the semiconductor substrate at least around a directly overlying region of a channel region of the N-type MOSFET and having tensile stress therein; and a compressive stress film provided in the directly overlying region of the channel region and having compressive stress therein.

### CROSS-REFERENCE TO RELATED APPLICATIONS

This application is based upon and claims the benefit of priority from the prior Japanese Patent Application No. 2007-269035, filed on Oct. 16, 2007; the entire contents of which are incorporated herein by reference.

### BACKGROUND OF THE INVENTION

1. Field of the Invention

This invention relates to a semiconductor device including a MOSFET (metal oxide semiconductor field effect transistor).

2. Background Art

Conventionally, in order to enhance the current driving performance of an N-type MOSFET (NMOS) formed in a semiconductor device, there is proposed a technique of covering the NMOS with a tensile stress film having tensile stress therein. Furthermore, in order to enhance the current driving performance of a P-type MOSFET (PMOS), there is proposed a technique of covering the PMOS with a compressive stress film having compressive stress therein (e.g., see JP-A-2003-060076 (Kokai)). By covering an NMOS with a tensile stress film, a tensile strain can be applied to the channel region of the NMOS to increase the electron mobility. Furthermore, by covering a PMOS with a compressive stress film, a compressive strain can be applied to the channel region of the PMOS to increase the hole mobility. However, recently, there has been demand for further enhancing the current driving performance of MOSFETs.

### SUMMARY OF THE INVENTION

According to an aspect of the invention, there is provided a semiconductor device including: a semiconductor substrate; an N-type MOSFET formed in a surface of the semiconductor substrate; a tensile stress film provided on the semiconductor substrate at least around a directly overlying region of a channel region of the N-type MOSFET and having tensile stress therein; and a compressive stress film provided in the directly overlying region of the channel region and having compressive stress therein.

According to another aspect of the invention, there is provided a semiconductor device including: a semiconductor substrate; an N-type MOSFET formed in a surface of the semiconductor substrate; and a tensile stress film provided on the semiconductor substrate at least around a directly overlying region of a channel region of the N-type MOSFET and having tensile stress therein, the N-type MOSFET having a gate electrode, the gate electrode being made of a compressive stress film which is conductive and has compressive stress therein.

According to still another aspect of the invention, there is provided a semiconductor device including: a semiconductor substrate; a P-type MOSFET formed in a surface of the semiconductor substrate; a compressive stress film provided on the semiconductor substrate at least around a directly overlying region of a channel region of the P-type MOSFET and having compressive stress therein; and a tensile stress film provided in the directly overlying region of the channel region and having tensile stress therein.

### BRIEF DESCRIPTION OF THE DRAWINGS

FIG. 1 is a cross-sectional view illustrating a semiconductor device according to a first embodiment of the embodiment;

FIGS. 2A to 2D are schematic views illustrating the operation principle of the first embodiment;

FIG. 3 is a schematic cross-sectional view showing the direction of forces applied to various portions of the semiconductor device according to the first embodiment;

FIG. 4 is a graph illustrating the effect of the thickness of the gate electrode on the on-current of the NMOS, where the horizontal axis represents the thickness of the gate electrode, and the vertical axis represents the increase rate of on-current;

FIG. 5A is a plan view illustrating a semiconductor device according to a first specific example of the first embodiment, and FIG. 5B is a cross-sectional view taken along line A-A′ shown in FIG. 5A;

FIGS. 6A and 6B are process cross-sectional views illustrating a method for manufacturing a semiconductor device according to the first specific example of the first embodiment;

FIGS. 7A and 7B are process cross-sectional views illustrating a method for manufacturing a semiconductor device according to the first specific example of the first embodiment;

FIGS. 8A and 8B are process cross-sectional views illustrating a method for manufacturing a semiconductor device according to the first specific example of the first embodiment;

FIG. 9A is a plan view illustrating a semiconductor device according to a second specific example of the first embodiment, and FIG. 9B is a cross-sectional view taken along line B-B′ shown in FIG. 9A;

FIGS. 10A and 10B are process cross-sectional views illustrating a method for manufacturing a semiconductor device according to the second specific example of the first embodiment;

FIGS. 11A and 11B are process cross-sectional views illustrating a method for manufacturing a semiconductor device according to the second specific example of the first embodiment;

FIGS. 12A and 12B are process cross-sectional views illustrating a method for manufacturing a semiconductor device according to the second specific example of the first embodiment;

FIG. 13 is a cross-sectional view illustrating a semiconductor device according to a third specific example of the first embodiment;

FIG. 14 is a cross-sectional view illustrating a semiconductor device according to a fourth specific example of the first embodiment;

FIG. 15 is a cross-sectional view illustrating a semiconductor device according to a fifth specific example of the first embodiment;

FIG. 16 is a schematic cross-sectional view illustrating a semiconductor device according to a second embodiment of the invention; and

FIG. 17 is a schematic cross-sectional view illustrating a semiconductor device according to a third embodiment of the invention.

### DETAILED DESCRIPTION OF THE INVENTION

Embodiments of the invention will now be described with reference to the drawings, beginning with a first embodiment of the invention.

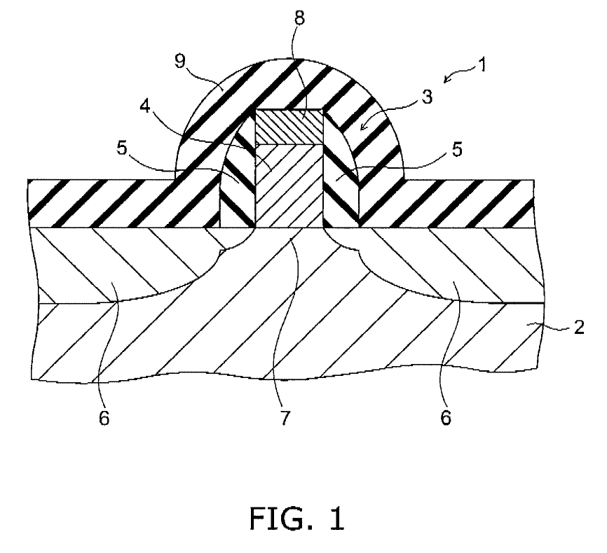

FIG. 1 is a cross-sectional view illustrating a semiconductor device according to this embodiment.

As shown in FIG. 1, the semiconductor device 1 according to this embodiment includes a silicon substrate 2 made of single crystal silicon (Si), and an N-type MOSFET (NMOS) 3 is formed in the surface of the silicon substrate 2.

More specifically, in the silicon substrate 2, at least part of its upper surface portion is of P-type. A gate oxide film (not shown) is formed at the surface of this P-type region, and a gate electrode 4 illustratively made of conductive polysilicon is provided on the gate oxide film. The gate electrode 4 has a striped shape extending perpendicular to the page of FIG. 1.

The thickness of the gate electrode 4 is illustratively 50 nanometers (nm) or less.

A sidewall 5 made of an insulator, such as silicon oxide (SiO₂) or silicon nitride (SiN), is provided on both lateral sides of the gate electrode 4. Furthermore, an N-type source/drain region 6 is formed in regions of the upper surface portion of the silicon substrate 2 sandwiching the directly underlying region of the gate electrode 4. This allows the directly underlying region of the gate electrode 4 in the silicon substrate 2, that is, the region between the source/drain regions 6, to serve as a P-type channel region 7. The channel region 7, the source/drain regions 6, the gate oxide film (not shown), the gate electrode 4, and the sidewalls 5 constitute the NMOS 3.

Furthermore, a compressive stress film 8 is buried in the directly overlying region of the gate electrode 4 between the sidewalls 5. That is, the compressive stress film 8 is provided directly above the channel region 7. The compressive stress film 8 itself tends to expand, but is constrained by the surroundings. Thus, it presses the surroundings and induces a reaction force, which generates compressive stress in the film. The compressive stress film 8 is illustratively formed from a material having a larger lattice constant than silicon.

As described below, the compressive stress film 8 is formed from a silicon compound (Si—X) formed by epitaxial growth on the gate electrode 4. For example, it is formed from silicon germanium (SiGe) deposited by plasma CVD (chemical vapor deposition). Alternatively, the compressive stress film 8 is illustratively formed from silicon nitride (SiN). This SiN is illustratively deposited by plasma CVD, and its hydrogen content is made higher than a prescribed threshold so that the lattice constant is larger than the lattice constant of silicon, thereby generating compressive stress.

Furthermore, a tensile stress film 9 is provided over the NMOS 3. The tensile stress film 9 is provided also in the region on the silicon substrate 2 outside the gate electrode 4. Thus, the tensile stress film 9 is provided also around the directly overlying region of the channel region 7. The tensile stress film 9 itself tends to shrink, but is constrained by the surroundings. Thus, it pulls the surroundings and induces a reaction force, which generates tensile stress in the film. The tensile stress film 9 is illustratively formed from a material having a smaller lattice constant than silicon.

As described below, the tensile stress film 9 is illustratively formed from silicon nitride (SiN) deposited by plasma CVD. The hydrogen content of this SiN is made lower than a prescribed threshold so that the lattice constant is smaller than the lattice constant of silicon, thereby generating tensile stress.

Next, the operation of the semiconductor device 1 according to this embodiment is described.

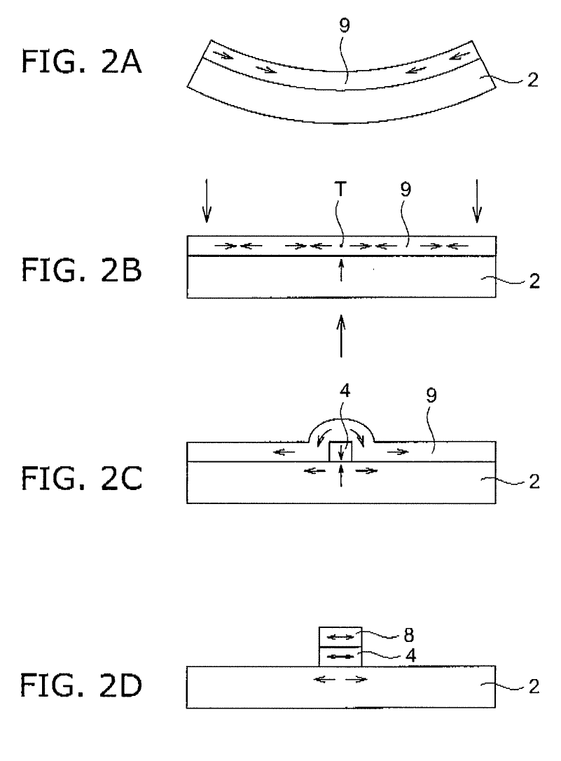

FIGS. 2A to 2D are schematic views illustrating the operation principle of this embodiment. In FIGS. 2A to 2D, for convenience, components other than those needed for the description are not shown.

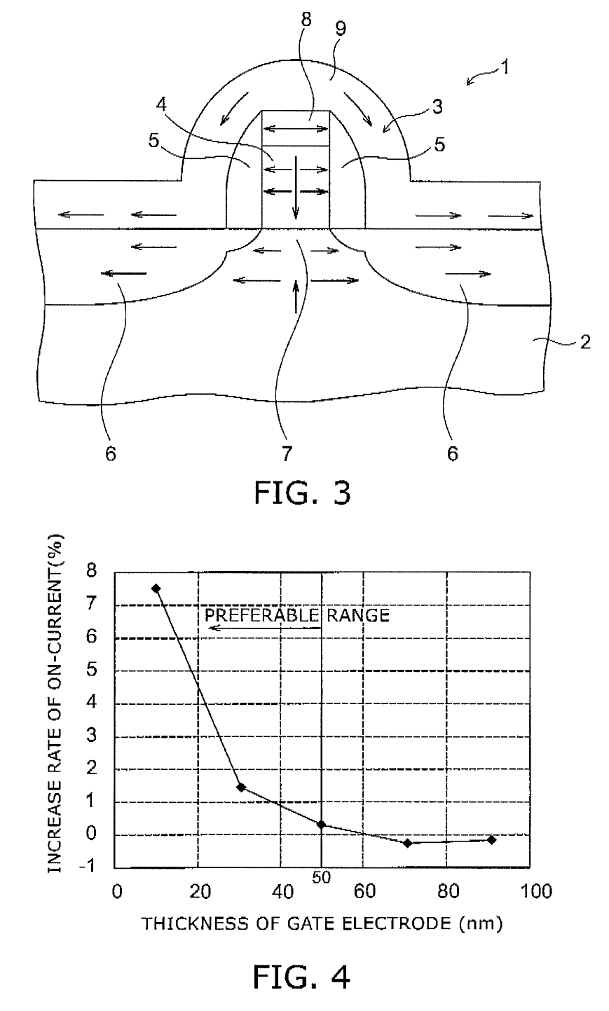

FIG. 3 is a schematic cross-sectional view showing the direction of forces applied to various portions of the semiconductor device according to this embodiment.

As shown in FIG. 2A, if a tensile stress film 9 is formed on the silicon substrate 2, the tensile stress film 9 itself tends to shrink. However, it is constrained by the silicon substrate 2, and hence induces tensile stress in the film. Here, if the silicon substrate 2 has a low rigidity, the silicon substrate 2 is bent so that the surface with the tensile stress film 9 formed thereon is concave, and the tensile stress in the tensile stress film 9 is alleviated.

However, as shown in FIG. 2B, if the silicon substrate 2 has a sufficiently high rigidity, the silicon substrate 2 is not bent significantly. In this case, the tensile stress in the tensile stress film 9 is not alleviated significantly, but a strong tensile stress remains. Here, any point T in the tensile stress film 9 is subjected to such a force as to pull it to both sides. That is, if a cut perpendicular to the film surface is made at the point T, this cut tends to expand naturally.

Hence, as shown in FIG. 2C, a gate electrode 4 provided between the silicon substrate 2 and the tensile stress film 9 is subjected to such a force as to pull it to both sides. Furthermore, a force is applied also to the silicon substrate 2 in the direction of separating from the gate electrode 4. Consequently, the directly underlying region of the gate electrode 4 in the silicon substrate 2 is subjected to such a force as to expand it to both sides. Furthermore, because the tensile stress film 9 itself tends to shrink, the gate electrode 4 is pressed toward the silicon substrate 2. This induces a reaction force from the silicon substrate 2 toward the gate electrode 4.

On the other hand, as shown in FIG. 2D, if a gate electrode 4 is provided on the silicon substrate 2 and a compressive stress film 8 is formed on the gate electrode 4, then the compressive stress film 8 itself tends to expand, and hence applies to the gate electrode 4 such a force as to push and expand the gate electrode 4. This force is transmitted to the silicon substrate 2 through the gate electrode 4, and the directly underlying region of the gate electrode 4 in the silicon substrate 2 is subjected to such a force as to push and expand this directly underlying region.

Hence, as shown in FIG. 3, in the semiconductor device 1 according to this embodiment, the tensile stress film 9 applies a force, in the direction of separating from each other, to the regions (source/drain regions 6) sandwiching the directly underlying region (channel region 7) of the gate electrode 4 in the silicon substrate 2, thereby pulling the channel region 7 toward the source/drain regions 6 on both sides. It is noted that the tensile stress film 9 is provided also directly above the gate electrode 4. However, the width of the gate electrode 4 is sufficiently smaller than the distance between the gate electrodes 4. Hence, the effect of the portion of the tensile stress film 9 located directly above the gate electrode 4 is negligible. Furthermore, the compressive stress film 8 applies to the gate electrode 4 such a force as to expand the gate electrode 4 to both lateral sides. This force is transmitted to the silicon substrate 2 through the gate electrode 4, thereby pushing and expanding the channel region 7 toward the source/drain regions 6 on both sides. The above forces, that is, the force applied to the channel region 7 by the tensile stress film 9 and the force applied to the channel region 7 by the compressive stress film 8 agree in direction with each other, and hence are constructively combined together. Thus, the channel region 7 is greatly strained along the arranging direction of the source/drain regions 6, that is, the direction of current flow, and increases the lattice constant in this direction. Consequently, the electron mobility in the channel region 7 increases, and the current driving performance of the NMOS 3 increases.

Next, the effect of this embodiment is described.

As described above, in this embodiment, the effects of the tensile stress film 9 and the compressive stress film 8 on the NMOS 3 can be combined together to provide an NMOS having a higher current driving performance than the conventional NMOS provided with only a tensile stress film.

In particular, in this embodiment, a large compressive stress and tensile stress can be obtained by forming the compressive stress film 8 from silicon nitride (SiN) or an epitaxially grown silicon compound (Si—X) and forming the tensile stress film 9 from silicon nitride (SiN). For example, a compressive stress of −2 GPa (gigapascals) and a tensile stress of +1.7 GPa can be obtained. Thus, in the NMOS of this embodiment, the on-current can be increased illustratively by several percent or more as compared with the conventional NMOS provided with only a tensile stress film.

In this regard, another method for obtaining compressive stress may be contemplated in which, for example, a silicon film is formed on the gate electrode and then expanded by thermal oxidation, However, this method needs high-temperature, long-time heat treatment for thermal oxidation of the silicon film, which increases the manufacturing cost, and may cause impurities introduced into the diffusion layer to diffuse beyond the allowable range. Furthermore, the compressive stress of the film thus formed is as small as approximately −0.3 GPa. Moreover, the compressive stress film formed by such a method is difficult to control in its film quality. Hence, preferably, the compressive stress film 8 is formed from silicon nitride (SiN) or an epitaxially grown silicon compound (Si—X).

Furthermore, in this embodiment, the gate electrode 4 has a thickness of 50 nanometers or less. This leads to high efficiency in transmitting the compressive stress of the compressive stress film 8 to the channel region 7, and the above-described effect of enhancing the current driving performance of the NMOS increases.

Next, a working example illustrating the effect of this embodiment is described.

FIG. 4 is a graph illustrating the effect of the thickness of the gate electrode on the on-current of the NMOS, where the horizontal axis represents the thickness of the gate electrode, and the vertical axis represents the increase rate of on-current.

In this working example, a simulation was performed for the NMOS 3 (see FIG. 1) in the above first embodiment to determine the value of on-current. Here, the total thickness of the gate electrode and the compressive stress film was 150 nanometers, and simulation was performed a plurality of times for various ratios of the thickness of the gate electrode to the thickness of the compressive stress film. The thickness of the gate electrode was varied in five levels within the range of 10 to 90 nanometers, and accordingly, the thickness of the compressive stress film was varied within the range of 60 to 140 nanometers. The compressive stress film was assumed to be a SiGe film having a stress of −3 GPa. The obtained value of on-current was compared with a comparative value, that is, the value of on-current determined for the NMOS of a comparative example provided with no compressive stress film on the gate electrode. The “increase rate of on-current” shown along the vertical axis of FIG. 4 is the increase rate of the simulation result relative to the comparative value. This increase rate of on-current was calculated by using piezoresistance coefficients based on the difference of stress in x, y, and z directions with reference to the stress value in the channel region of the NMOS provided with no compressive stress film on the gate electrode.

As shown in FIG. 4, in this simulation, the on-current of the NMOS increased as the thickness of the gate electrode became thinner, that is, with the decrease of the distance from the interface between the compressive stress film and the gate electrode to the interface between the gate electrode to the gate oxide film. This is presumably because, as the thickness of the gate electrode becomes thinner, force is more easily transmitted from the compressive stress film to the channel region and enhances the effect of varying the lattice constant of the channel region to increase the electron mobility. In this simulation, when the thickness of the gate electrode was 50 nanometers (nm) or less, the effect of increasing the on-current was clearly observed. Hence, it is preferable that the thickness of the gate electrode be 50 nanometers or less. It is noted that, by adjusting conditions such as the thickness of the compressive stress film and the magnitude of the stress, the effect of increasing the on-current can be achieved even if the gate electrode is more than 50 nanometers.

In the following, specific examples for implementing the above first embodiment are described, beginning with a first specific example.

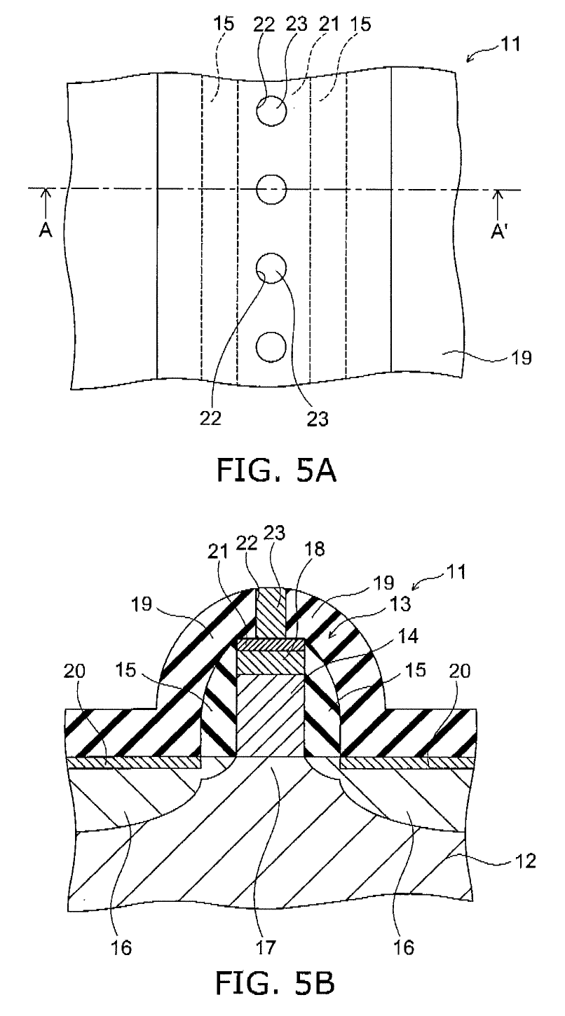

FIG. 5A is a plan view illustrating a semiconductor device according to this specific example, and FIG. 5B is a cross-sectional view taken along line A-A′ shown in FIG. 5A.

In this specific example, a conductive compressive stress film is formed.

As shown in FIGS. 5A and 5B, the semiconductor device 11 according to this specific example has the same basic structure as the semiconductor device 1 according to the above first embodiment (see FIG. 1). More specifically, the semiconductor device 11 includes a silicon substrate 12 made of single crystal silicon. At least part of the upper surface portion in the silicon substrate 12 is a region having P-type conductivity, and a gate oxide film (not shown) is formed at the surface of this P-type region. A gate electrode 14 made of conductive polysilicon and having a striped shape is provided on the gate oxide film. A sidewall 15 illustratively made of silicon oxide is provided on both side surfaces of the gate electrode 14.

On the other hand, an N-type source/drain region 16 is formed in regions of the upper surface portion of the silicon substrate 12 sandwiching the directly underlying region of the gate electrode 14. The region therebetween, that is, the directly underlying region of the gate electrode 14, serves as a P-type channel region 17. The channel region 17, the source/drain regions 16, the gate oxide film (not shown), the gate electrode 14, and the sidewalls 15 constitute the NMOS 13. Furthermore, a suicide film 20 is formed at the surface of the source/drain region 16. The silicide film 20 is formed from a silicide, such as NiSi.

Furthermore, a compressive stress film 18 is buried in the directly overlying region of the gate electrode 14 between the sidewalls 15. The compressive stress film 18 is made of a conductive silicon compound (Si—X) formed by epitaxial growth, and illustratively formed from silicon germanium (SiGe). Hence, the compressive stress film 18 is conductive. In the case where the compressive stress film 18 is formed from SiGe, the concentration of Ge is not particularly limited as long as the lattice constant of SiGe is larger than the lattice constant of Si. By way of example, the Ge concentration in SiGe is 20 atomic %. A suicide film 21 made of a silicide, such as NiSi, is formed at the surface of the compressive stress film 18.

Furthermore, a tensile stress film 19 is provided over the NMOS 13. The tensile stress film 19 is provided also around the directly overlying region of the channel region 17. The tensile stress film 19 is illustratively formed from silicon nitride (SiN). A contact hole 22 is formed in a portion of the tensile stress film 19 located directly above the gate electrode 14. A metal, such as tungsten (W), is buried inside the contact hole 22 to constitute a contact 23. The contact 23 is connected to the suicide film 21, and connected to the gate electrode 14 through the silicide film 21 and the compressive stress film 18. As viewed in the direction perpendicular to the surface of the silicon substrate 12, the contacts 23 are spaced from each other in a line along the extending direction of the gate electrode 14. A contact (not shown) is also formed in a portion of the tensile stress film 19 located directly above the source/drain region 6, penetrates the tensile stress film 19, and is connected to the suicide film 20.

Next, a method for manufacturing a semiconductor device according to this specific example is described.

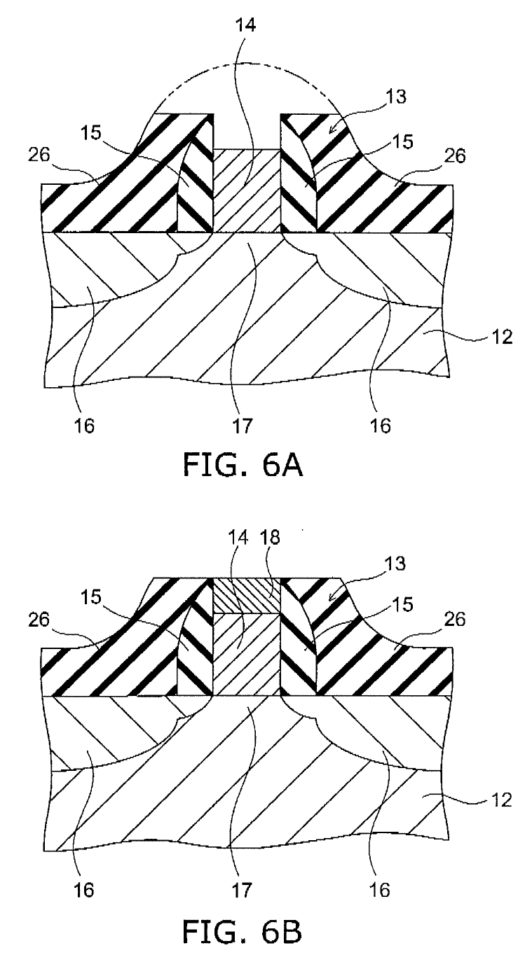

FIGS. 6A, 6B, 7A, 7B, 8A, and 8B are process cross-sectional views illustrating a method for manufacturing a semiconductor device according to this specific example, First, as shown in FIG. 6A, an NMOS 13 is fabricated by conventional methods. More specifically, a gate oxide film (not shown) is formed on a silicon substrate 12. Then, a gate electrode 14 and a sidewall 15 are formed on the gate oxide film, and a source/drain region 16 is formed in the silicon substrate 12. The region between the source/drain regions 16 serves as a channel region 17.

Next, a silicon nitride film 26 is formed on the entire surface. The surface of this silicon nitride film 26 is planarized by CMP (chemical mechanical polishing) to expose the gate electrode 14. The silicon nitride film 26 is used as a mask to apply RIE (reactive ion etching) to the gate electrode 14. Thus, the upper surface portion of the gate electrode 14 is removed, and a recess is formed between the sidewalls 15.

Next, as shown in FIG. 6B, cleaning is performed by conventional methods. Then, a silicon compound (Si—X) such as SiGe, which is conductive and has a larger lattice constant than silicon, is epitaxially grown on the gate electrode 14 by plasma CVD. Thus, a compressive stress film 18 is formed above the gate electrode 14 between the sidewalls 15. Then, the silicon nitride film 26 is removed.

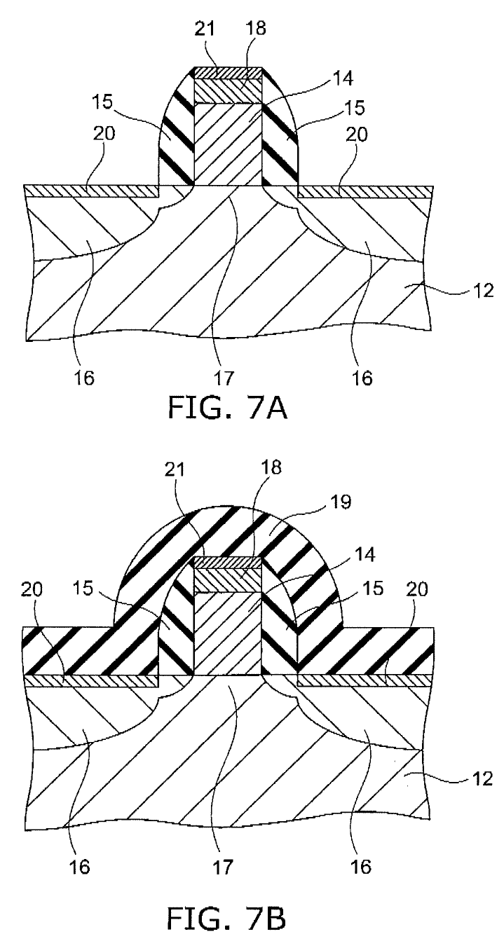

Next, as shown in FIG. 7A, nickel (Ni) is deposited on the entire surface and heat treated to form NiSi in the exposed portion of silicon. Thus, a silicide film 20 is formed at the surface of the source/drain region 16, and a silicide film 21 is formed at the surface of the compressive stress film 18. Then, unreacted nickel is removed.

Next, as shown in FIG. 7B, silicon nitride (SiN) is deposited by plasma CVD using NH₃ gas and SiH₄ gas as raw materials. It is noted that the growth of SiN at this time is not epitaxial. Furthermore, at this time, the ratio of the flow rate of NH₃ gas to the flow rate of SiH₄ gas (hereinafter referred to as “NH₃/SiH₄ flow rate ratio”) is made relatively small so that the hydrogen content in the SiN film is lower than a prescribed threshold. Hence, the SiN film has a smaller lattice constant than silicon, and generates tensile stress in the film. Thus, a tensile stress film 19 made of SiN is formed over the NMOS 13.

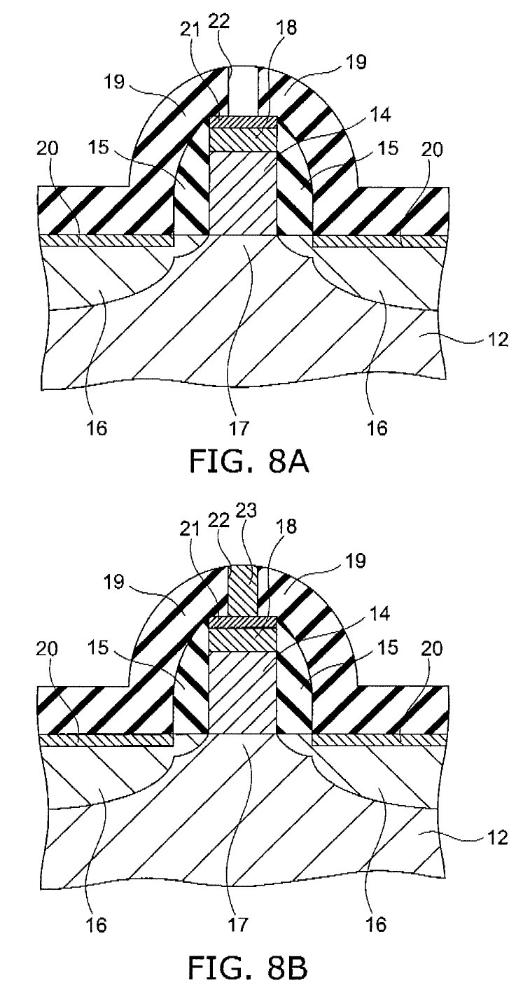

Next, as shown in FIG. 8A, the tensile stress film 19 is buried illustratively with a silicon oxide film (not shown). By photolithography, a contact hole 22 is formed through this silicon oxide film at a position of the tensile stress film 19 corresponding to the directly overlying region of the silicide film 21. Likewise, a contact hole (not shown) is also formed at a position corresponding to the directly overlying region of the silicide film 20.

Next, as shown in FIG. 8B, a metal, such as tungsten, is buried in the contact hole 22 to form a contact 23 connected to the silicide 21. Likewise, a contact (not shown) connected to the suicide film 20 is also formed. Thus, the semiconductor device 11 shown in FIGS. 5A and 5B is manufactured.

Next, the operation and effect of this specific example are described.

On the principle described in the above first embodiment, also in the semiconductor device 11 according to this specific example, the effects of the compressive stress film 18 and the tensile stress film 19 can be combined together to enhance the current driving performance of the NMOS 13. For example, in the case where the compressive stress film 18 is formed from SiGe having a Ge concentration of 20 atomic %, the on-current can be increased by approximately several percent as compared with the NMOS provided with no compressive stress film.

Furthermore, in this specific example, the compressive stress film 18 is formed from SiGe, which is conductive, and a silicide film 21 is formed at the surface of the compressive stress film 18. Hence, the gate electrode 14 can be connected to the contact 23 through the compressive stress film 18 and the silicide film 21. The operation and effect in this specific example other than the foregoing are the same as those in the above first embodiment.

Next, a second specific example of the first embodiment is described.

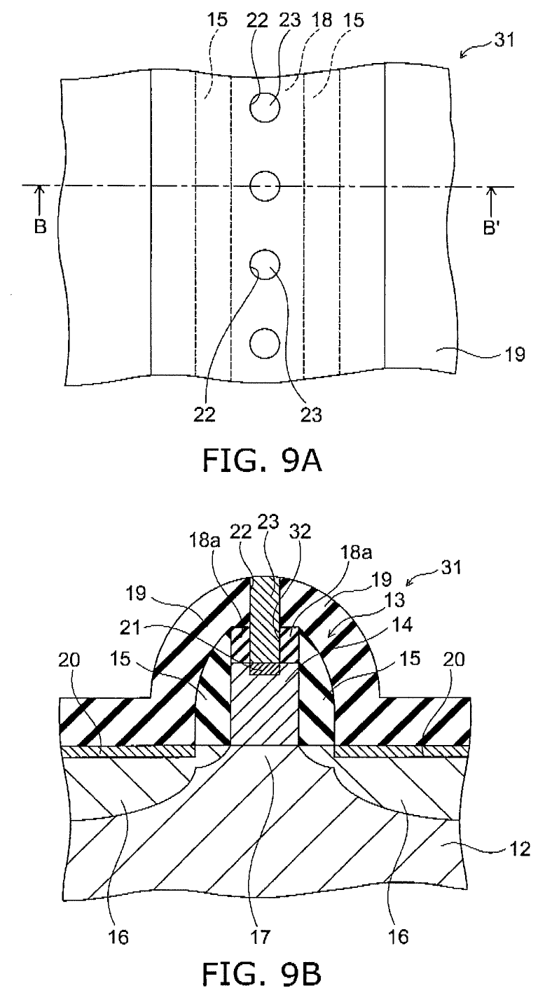

FIG. 9A is a plan view illustrating a semiconductor device according to this specific example, and FIG. 9B is a cross-sectional view taken along line B-B′ shown in FIG. 9A.

As shown in FIGS. 9A and 9B, the semiconductor device 31 according to this specific example is different from the semiconductor device 11 according to the above first specific example in that the compressive stress film 18a is formed from silicon nitride (SiN), which is insulative, and that the contact 23 penetrates the tensile stress film 19 and the compressive stress film 18a and reaches the gate electrode 14. Furthermore, the silicide film 21 is formed not at the surface of the compressive stress film 18a, but in a region of the surface of the gate electrode 14 corresponding to the directly underlying region of the contact 23, that is, at the bottom of the contact hole 22. Thus, the contact 23 is connected to the gate electrode 14 without the intermediary of the compressive stress film 18a. The configuration of this specific example other than the foregoing is the same as that of the above first specific example.

Next, a method for manufacturing a semiconductor device according to this specific example is described.

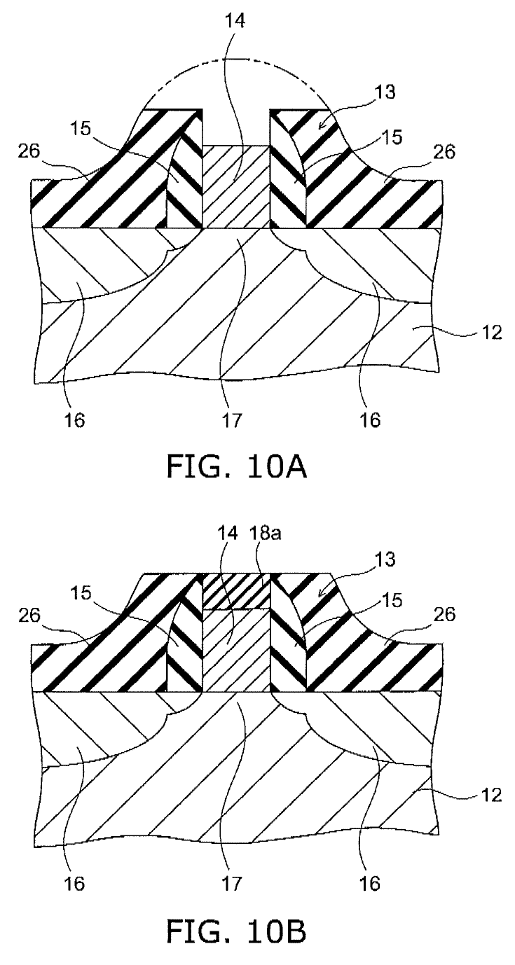

FIGS. 10A, 10B, 11A, 11B, 12A, and 12B are process cross-sectional views illustrating a method for manufacturing a semiconductor device according to this specific example.

First, as shown in FIG. 10A, by conventional methods, a gate oxide film (not shown), a gate electrode 14 and a sidewall 15 are formed on a silicon substrate 12, and a source/drain region 16 and a channel region 17 are formed in the silicon substrate 12. Thus, an NMOS 13 is fabricated. Next, a silicon nitride film 26 is formed on the entire surface, and its surface is planarized by CMP to expose the gate electrode 14. Next, the silicon nitride film 26 is used as a mask to etch the gate electrode 14, thereby removing its upper surface portion.

Next, as shown in FIG. 10B, silicon nitride (SiN) is deposited on the gate electrode 14 by plasma CVD using NH₃ gas and SiH₄ gas as raw materials. Thus, a compressive stress film 18a is formed above the gate electrode 14 between the sidewalls 15. It is noted that the growth of SiN at this time is not epitaxial. Furthermore, at this time, the NH₃/SiH₄ flow rate ratio is made relatively large so that the hydrogen content in the SiN film is higher than a prescribed threshold. Hence, the SiN film has a larger lattice constant than silicon, and generates compressive stress in the film. Thus, a compressive stress film 18a made of SiN is formed. Then, the silicon nitride film 26 is removed.

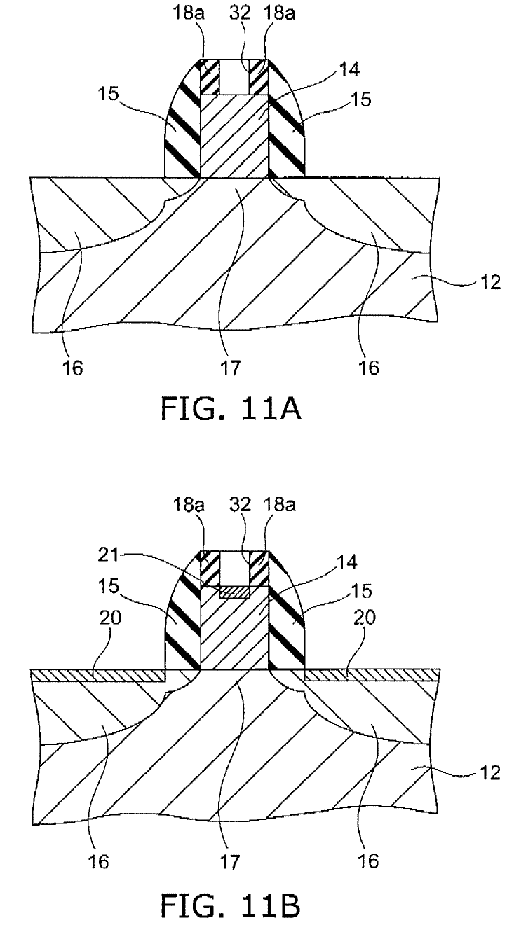

Next, as shown in FIG. 11A, by photolithography, a contact hole 32 reaching the gate electrode 14 is formed in the compressive stress film 18a. Next, as shown in FIG. 11b, nickel (Ni) is deposited on the entire surface and heat treated to form NiSi in the exposed portion of silicon. Thus, a suicide film 20 is formed at the surface of the source/drain region 16, and a suicide film 21 is formed at the surface of the gate electrode 14, that is, at the bottom of the contact hole 32. Then, unreacted nickel is removed.

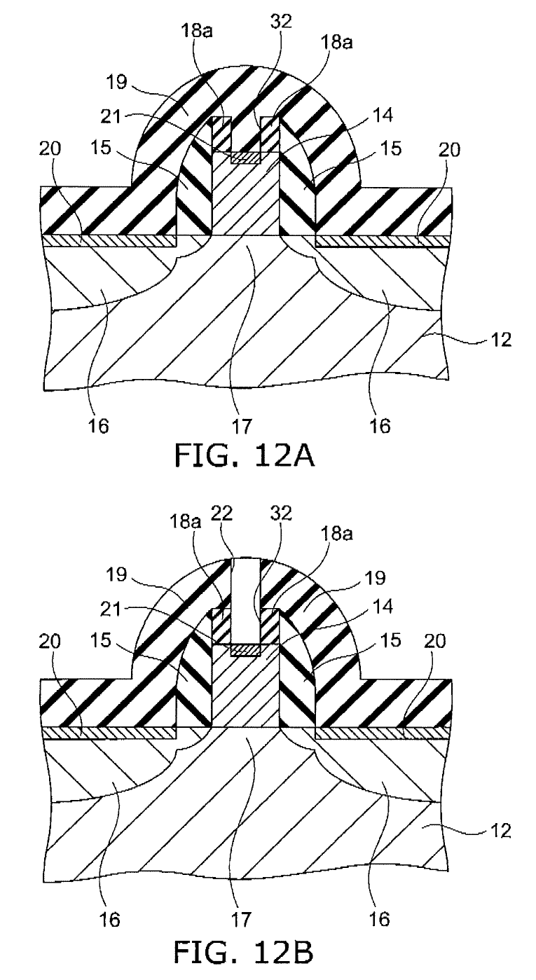

Next, as shown in FIG. 12A, silicon nitride (SiN) is deposited by plasma CVD. Thus, a tensile stress film 19 is formed over the NMOS 13. The method for forming the tensile stress film 19 is the same as that of the above first specific example. More specifically, in plasma CVD using NH₃ gas and SiH₄ gas as raw materials, the NH₃/SiH₄ flow rate ratio is made relatively small so that the hydrogen content in the SiN film is lower than a prescribed threshold. Hence, the SiN film has a smaller lattice constant than silicon, and generates tensile stress in the film.

Thus, in forming the SiN film by plasma CVD, the NH₃/SiH₄ flow rate ratio can be adjusted to control the direction and magnitude of stress in the film. That is, if the NH₃/SiH₄ flow rate ratio is decreased to decrease hydrogen content in the film, the lattice constant of SiN becomes smaller than the lattice constant of Si, and a tensile stress occurs. On the other hand, if the NH₃/SiH₄ flow rate ratio is increased to increase hydrogen content in the film, the lattice constant of SiN becomes larger than the lattice constant of Si, and a compressive stress occurs.

Next, as shown in FIG. 12B, a contact hole 22 is formed in the tensile stress film 19 directly above the contact hole 32. Likewise, a contact hole (not shown) is also formed at a position of the tensile stress film 19 corresponding to the directly overlying region of the silicide film 20.

Next, as shown in FIGS. 9A and 9B, a metal, such as tungsten, is buried in the contact holes 22 and 32 to form a contact 23 connected to the silicide 21. Likewise, a contact (not shown) connected to the suicide film 20 is also formed. Thus, the semiconductor device 31 according to this specific example is manufactured.

In this specific example, the compressive stress film 18a is formed from SiN, which is insulative. However, a suicide film 21 is formed at the surface of the gate electrode 14, and the contact 23 is allowed to penetrate the tensile stress film 19 and the compressive stress film 18a. Hence, the contact 23 can be connected to the gate electrode 14. The operation and effect in this specific example other than the foregoing are the same as those in the above first specific example.

Next, a third specific example of the first embodiment is described.

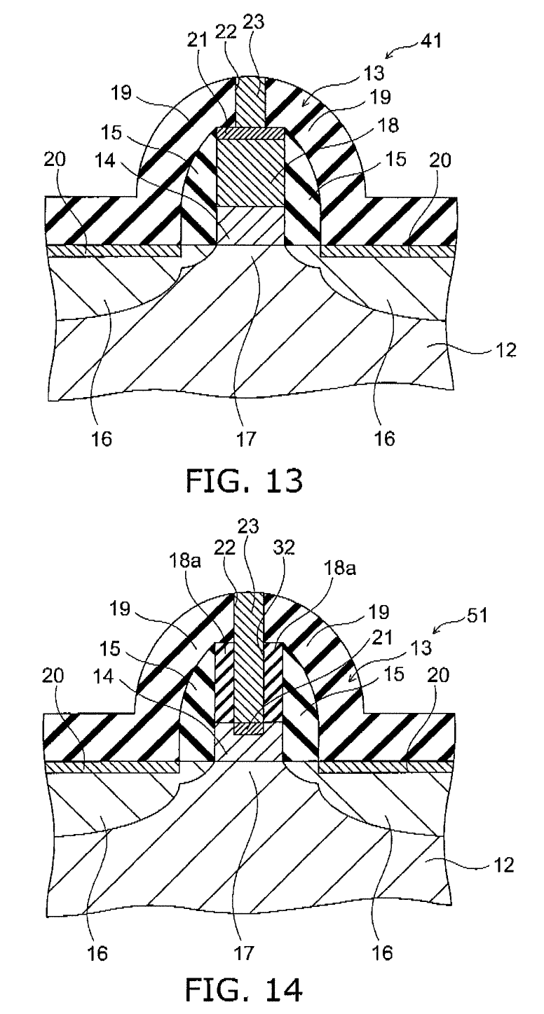

FIG. 13 is a cross-sectional view illustrating a semiconductor device according to this specific example.

As shown in FIG. 13, in the semiconductor device 41 according to this specific example, the gate electrode 14 has a smaller thickness than the compressive stress film 18. The gate electrode 14 has a thickness of 50 nanometers (nm) or less. The configuration and manufacturing method in this specific example other than the foregoing are the same as those in the above first specific example.

According to this specific example, the compressive stress film 18 is formed relatively thick, which results in a large force applied to the gate electrode 14 by the compressive stress film 18. Furthermore, the gate electrode 14 is formed relatively thin so that the force applied from the compressive stress film 18 is transmitted to the channel region 17 with high efficiency. Consequently, the channel region 17 can be strained more greatly, and the current driving performance of the NMOS 13 can be further enhanced. The operation and effect in this specific example other than the foregoing are the same as those In the above first specific example.

Next, a fourth specific example of the first embodiment is described.

FIG. 14 is a cross-sectional view illustrating a semiconductor device according to this specific example.

As shown in FIG. 14, this specific example is a combination of the second specific example and the third specific example described above. More specifically, in the semiconductor device 51 according to this specific example, like the above third specific example, the gate electrode 14 has a smaller thickness than the compressive stress film 18. Furthermore, like the above second specific example, the compressive stress film 18a is formed from an insulative material, such as silicon nitride (SiN), and the contact 23 penetrates the compressive stress film 18 and is connected to the gate electrode 14. The configuration and manufacturing method in this specific example other than the foregoing are the same as those in the above second specific example. The operation and effect in this specific example other than the foregoing are the same as those in the above second or third specific example.

Next, a fifth specific example of the first embodiment is described.

FIG. 15 is a cross-sectional view illustrating a semiconductor device according to this specific example.

As shown in FIG. 15, the semiconductor device 61 according to this specific example is different from the semiconductor device according to the above first specific example (see FIG. 5) in that the gate electrode 14 made of polysilicon (see FIG. 5B) is not provided, but the conductive compressive stress film 18 serves as a gate electrode. That is, only the gate oxide film (not shown) is interposed between the channel region 17 and the compressive stress film 18. Furthermore, a suicide film 21 is formed at the surface of the compressive stress film 18, and a contact 23 buried in the tensile stress film 19 is connected to this silicide film 21. Such a semiconductor device can be manufactured, for example, by completely removing the gate electrode 14 by RIE in the step of applying RIE to the gate electrode 14 in the above first specific example (see FIG. 6A). The configuration and manufacturing method in this specific example other than the foregoing are the same as those in the above first specific example.

According to this specific example, the compressive stress film 18 can be formed thick so that the force applied to the channel region 17 can be increased. Furthermore, because the compressive stress film 18 applies force directly to the channel region 17 without the intermediary of the gate electrode 14 (see FIG. 5B), the compressive force of the compressive stress film 18 is transmitted to the channel region 17 very efficiently, and the current driving performance of the NMOS 13 can be further enhanced. The operation and effect in this specific example other than the foregoing are the same as those in the above first specific example.

Next, a second embodiment of the invention is described.

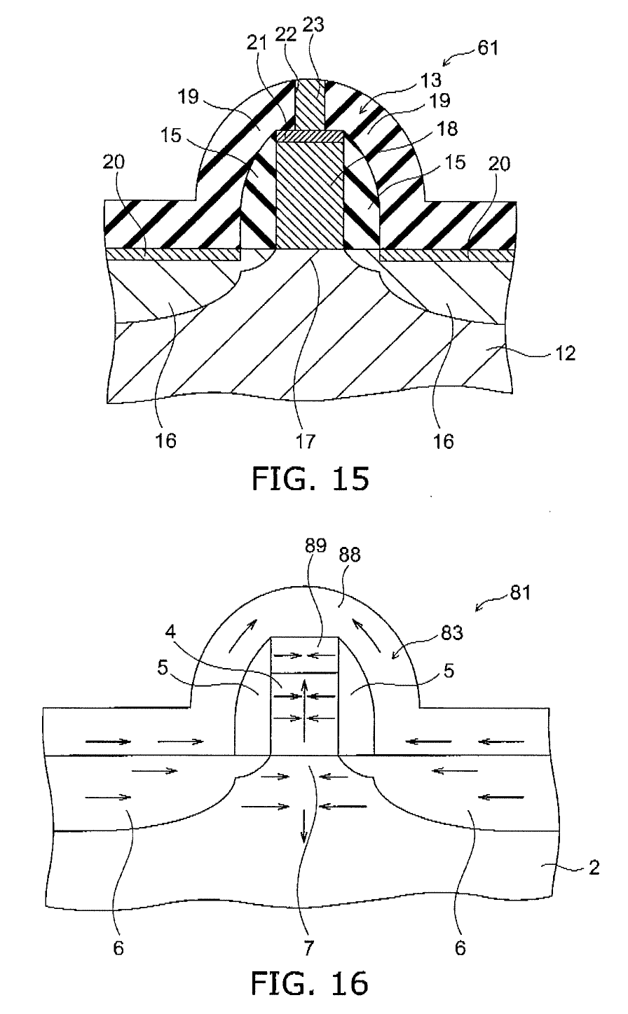

FIG. 16 is a schematic cross-sectional view illustrating a semiconductor device according to this embodiment.

Like FIG. 3, FIG. 16 also shows the direction of forces applied to various portions of the semiconductor device.

As shown in FIG. 16, in the semiconductor device 81 according to this embodiment, a P-type MOSFET (PMOS) 83 is formed in the surface of a silicon substrate 2 made of single crystal silicon. The configuration of the PMOS 83 is the same as the NMOS 3 in the above first embodiment (see FIG. 1) except that the conductivity type of each portion is reversed.

Furthermore, a tensile stress film 89 is buried in the directly overlying region of the gate electrode 4 between the sidewalls 5. That is, the tensile stress film 89 is provided directly above the channel region 7. Like the tensile stress film 9 in the above first embodiment, the tensile stress film 89 itself tends to shrink, but is constrained by the surroundings. Thus, it pulls the surroundings and induces a reaction force, which generates tensile stress in the film. The tensile stress film 89 is illustratively formed from silicon carbide (SiC). Alternatively, the tensile stress film 89 can be formed from SiN, which is deposited by plasma CVD and has a smaller lattice constant than silicon.

Furthermore, a compressive stress film 88 is provided over the PMOS 83. That is, the compressive stress film 88 is provided also around the directly overlying region of the channel region 7. Like the compressive stress film 8 in the above first embodiment, the compressive stress film 88 itself tends to expand, but is constrained by the surroundings. Thus, it presses the surroundings and induces a reaction force, which generates compressive stress in the film. The compressive stress film 88 is illustratively a SiGe film, which is deposited by plasma CVD and has a larger lattice constant than silicon.

Next, the operation and effect of the semiconductor device 81 according to this embodiment are described.

As shown in FIG. 16, in the semiconductor device 81 according to this embodiment, the direction of forces applied to various portions is reversed with respect to the above first embodiment. More specifically, the compressive stress film 88 located around the directly overlying region of the channel region 7 applies a force to the source/drain regions 6 in the direction of coming close to each other, thereby compressing the channel region 7 from both sides, that is, the sides of the source/drain regions 6. Furthermore, the compressive stress film 88 pulls the gate electrode 4 upward, that is, in the direction of separating from the silicon substrate 2. On the other hand, the tensile stress film 89 located directly above the channel region 7 applies a force to the gate electrode 4 in the direction of compressing it from both sides. This force is transmitted to the silicon substrate 2 through the gate electrode 4, thereby compressing the channel region 7 along the arranging direction of the source/drain regions 6.

The above forces, that is, the force applied to the channel region 7 by the compressive stress film 88 and the force applied to the channel region 7 by the tensile stress film 89 are constructively combined together. Thus, the channel region 7 is greatly strained along the direction of current flow, and decreases the lattice constant in this direction. Consequently, the hole mobility in the channel region 7 increases, and the current driving performance of the PMOS 83 increases.

Next, the effect of this embodiment is described.

As described above, in this embodiment, the effects of the compressive stress film 88 and the tensile stress film 89 on the PMOS 83 can be combined together to provide a PMOS having a higher current driving performance.

A simulation similar to that in the working example of the above first embodiment was performed for the PMOS 83 in this embodiment. In the case of providing a tensile stress film on the gate electrode, a result similar to that shown in FIG. 4 was obtained.

The semiconductor device according to this embodiment can also be implemented in a similar manner to the first to fifth specific example of the above first embodiment.

Next, a third embodiment of the invention is described.

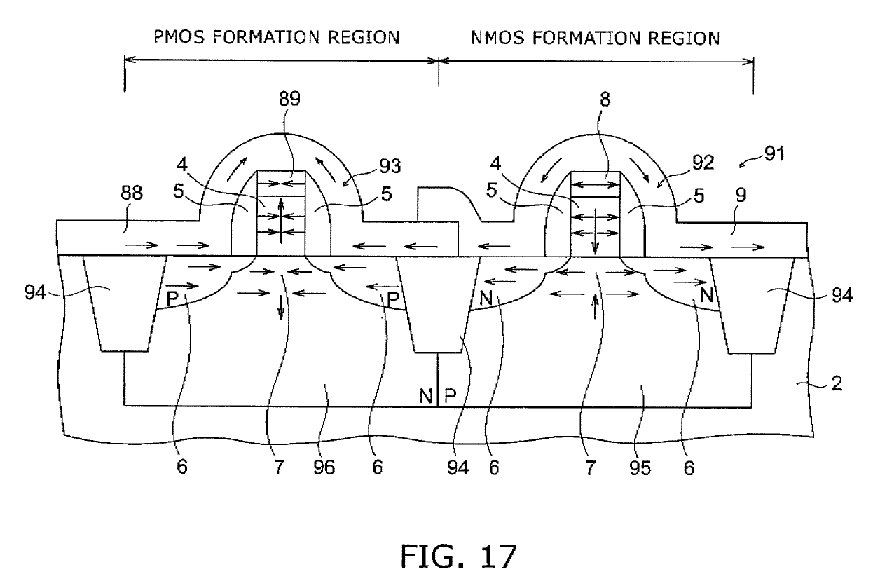

FIG. 17 is a schematic cross-sectional view illustrating a semiconductor device according to this embodiment.

Like FIG. 3, FIG. 17 also shows the direction of forces applied to various portions of the semiconductor device.

As shown in FIG. 17, in the semiconductor device 91 according to this embodiment, a device isolation film 94 is selectively formed in the surface of a silicon substrate 2 made of single crystal silicon, By this device isolation film 94, the silicon substrate 2 is divided into a plurality of regions, which are insulated from each other. One of the divided regions is an NMOS formation region, and another is a PMOS formation region.

A P-well 95 is formed in the NMOS formation region, and an NMOS 92 is formed in the surface of the P-well 95. The NMOS 92 has the same configuration as the NMOS 3 in the above first embodiment. A compressive stress film 8 is provided directly above the channel region of the NMOS 92, and a tensile stress film 9 is provided over the NMOS 92.

On the other hand, an N-well 96 is formed in the PMOS formation region, and a PMOS 93 is formed in the surface of the N-well 96. The PMOS 93 has the same configuration as the PMOS 83 according to the above second embodiment. A tensile stress film 89 is provided directly above the channel region of the PMOS 93, and a compressive stress film 88 is provided over the PMOS 93.

According to this embodiment, the electron mobility in the NMOS 92 is increased by an operation similar to the above first embodiment, and the hole mobility in the PMOS 93 is increased by an operation similar to the above second embodiment. Thus, the current driving performance of both the NMOS 92 and the PMOS 93 can be enhanced.

The semiconductor device according to this embodiment can also be implemented in a similar manner to the first to fifth specific example of the above first embodiment.

The features of the invention have been described with reference to the embodiments and the specific examples thereof. However, the invention is not limited to these embodiments and specific examples. For example, those skilled in the art can suitably modify the design of the above embodiments and specific examples, modify the process steps thereof, and add/delete components or process steps. Such modifications are also encompassed within the scope of the invention as long as they fall within the spirit of the invention.

1. A semiconductor device comprising;
a semiconductor substrate;
an N-type MOSFET formed in a surface of the semiconductor substrate;
a tensile stress film provided on the semiconductor substrate at least around a directly overlying region of a channel region of the N-type MOSFET and having tensile stress therein; and
a compressive stress film provided in the directly overlying region of the channel region and having compressive stress therein.

2. The device according to claim 1, wherein
the N-type MOSFET has a gate electrode made of silicon, and
the compressive stress film is formed by epitaxial growth on the gate electrode and made of a silicon compound having a larger lattice constant than silicon.

3. The device according to claim 2, wherein the silicon compound is silicon germanium.

4. The device according to claim 3, wherein a silicide film is formed at a surface of the compressive stress film.

5. The device according to claim 1, wherein the compressive stress film is conductive.

6. The device according to claim 1, wherein
the compressive stress film is formed on a gate electrode of the N-type MOSFET and made of a silicon nitride having a larger lattice constant than silicon, and
the semiconductor device further comprising:
a contact penetrating the compressive stress film and connected to the gate electrode.

7. The device according to claim 1, wherein the tensile stress film is made of a silicon nitride having a smaller lattice constant than silicon.

8. The device according to claim 1, wherein the compressive stress film and the tensile stress film are each made of silicon nitride, and the compressive stress film has a higher hydrogen content than the tensile stress film.

9. The device according to claim 1, wherein the N-type MOSFET has a gate electrode which has a smaller thickness than the compressive stress film.

10. The device according to claim 1, wherein the N-type MOSFET has a gate electrode which has a thickness of 50 nanometers or less.

11. A semiconductor device comprising:
a semiconductor substrate;
an N-type MOSFET formed in a surface of the semiconductor substrate; and
a tensile stress film provided on the semiconductor substrate at least around a directly overlying region of a channel region of the N-type MOSFET and having tensile stress therein,
the N-type MOSFET having a gate electrode, the gate electrode being made of a compressive stress film which is conductive and has compressive stress therein.

12. The device according to claim 11, wherein the compressive stress film is made of silicon germanium.

13. A semiconductor device comprising;
a semiconductor substrate;
a P-type MOSFET formed in a surface of the semiconductor substrate;
a compressive stress film provided on the semiconductor substrate at least around a directly overlying region of a channel region of the P-type MOSFET and having compressive stress therein; and
a tensile stress film provided in the directly overlying region of the channel region and having tensile stress therein.

14. The device according to claim 13, wherein the tensile stress film is made of a silicon nitride having a smaller lattice constant than silicon.

15. The device according to claim 13, wherein the tensile stress film is made of silicon carbide.

16. The device according to claim 13, wherein the compressive stress film is made of a silicon compound having a larger lattice constant than silicon.

17. The device according to claim 16, wherein the silicon compound is silicon germanium.

18. The device according to claim 13, wherein the compressive stress film and the tensile stress film are each made of silicon nitride, and the compressive stress film has a higher hydrogen content than the tensile stress film.

19. The device according to claim 13, wherein the N-type MOSFET has a gate electrode which has a smaller thickness than the compressive stress film.

20. The device according to claim 13, wherein the N-type MOSFET has a gate electrode which has a thickness of 50 nanometers or less.
